(19) United States
(12) Patent Application Publication
(10) Pub. No.: US 2014/0355360 A1
(43) Pub. Date: Dec. 4, 2014

(54) HIGH SPEED AND LOW OFFSET SENSE AMPLIFIER

(71) Applicant: UNITED MICROELECTRONICS CORP., Hsin-Chu City (TW)

(72) Inventor: Hsi-Wen Chen, Kaohsiung City (TW)

(21) Appl. No.: 13/906,352

(22) Filed: May 31, 2013

(51) Int. Cl. G11C 7/08; G11C 7/06

(52) U.S. Cl. CPC G11C 7/08; G11C 7/067; G11C 7/065
USPC 365/189.06

(57) ABSTRACT

A sense amplifier includes a sensing circuit and an equalizing circuit. The sensing circuit is configured to supply one or more output signals according to one or more input signals. The equalizing circuit is configured to bring the sensing circuit to a metastable state from which the sensing circuit switches to an inverting state in response to a potential of the one or more input signals. Each transistor in the sensing circuit may switch to logic 0 or logic 1 faster and die-to-die PVT variations may be compensated, thereby providing high speed and low offset read operation.

### BACKGROUND OF THE INVENTION

1. Field of the Invention

The present invention is related to a sense amplifier, and more particularly, to a high speed and low offset current-latch type sense amplifier for SRAM application.

2. Description of the Prior Art

Sense amplifiers are used to detect differences between two voltages and common applications include reading the contents of memory cells in memory arrays. Sense amplifiers may adopt single-ended or differential schemes. A single-ended sense amplifier determines the state of a memory cell by comparing the potential of a single sense input with an internal current source or voltage source. A differential sense amplifier determines the state of a memory cell by comparing the relative voltages of two sense inputs and provides an output signal representative of a data value stored within the memory cell.

A typical sense amplifier includes a plurality of transistors whose characteristics may vary due to process, voltage, and temperature (PVT) variations. Such performance mismatch has great impact on the sensing ability of the sense amplifier. Therefore, there is a need for a high speed sense amplifier capable of compensating die-to-die PVT variations.

### SUMMARY OF THE INVENTION

The present invention provides a single-ended sense amplifier including an input node arranged to receive an input signal and a reference signal; an output node arranged to output an output signal which reflects the input signal; a sensing circuit coupled between the input node and the output node; and an equalizing circuit connected between the input node and the output node. The sensing circuit is configured to detect a potential of the input node and generate an output signal according to the potential of the input node. The equalizing circuit is configured to bring the sensing circuit to a metastable state from which the sensing circuit switches to a high-level state or a low-level state in response to the potential of the input node crossing a threshold voltage.

The present invention also provides a differential sense amplifier including a first input node arranged to receive a first input signal; a second input node arranged to receive a second input signal; a first output node arranged to output a first output signal; a second output node arranged to output a second output signal; a sensing circuit coupled to the first input node, the second input node, the first output node and the second output node; and an equalizing circuit connected between the first output node and the second output node. The sensing circuit is configured to detect a potential of the first input node and a potential of the second input node and generate the first output signal and the second output signal according to a potential difference between the first input node and the second input node in an inverting state, wherein a potential difference between the first output signal and the second output signal reflects the potential difference between the first input signal and the second input signal. The equalizing circuit is configured to bring the sensing circuit to a metastable state from which the sensing circuit switches to the inverting state in response to the potential difference between the first input node and the second input node crossing a predetermined value.

The present invention also provides a sense amplifier including a first input node arranged to receive a first input signal; a first output node arranged to output a first output signal; a sensing circuit configured to supply the first output signal according to the first input signal; and an equalizing circuit configured to bring the sensing circuit to a metastable state from which the sensing circuit switches to an inverting state in response to a potential of the first input node crossing a first value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1˜2 are diagrams illustrating a sense amplifier according to embodiments of the present invention.

### DETAILED DESCRIPTION

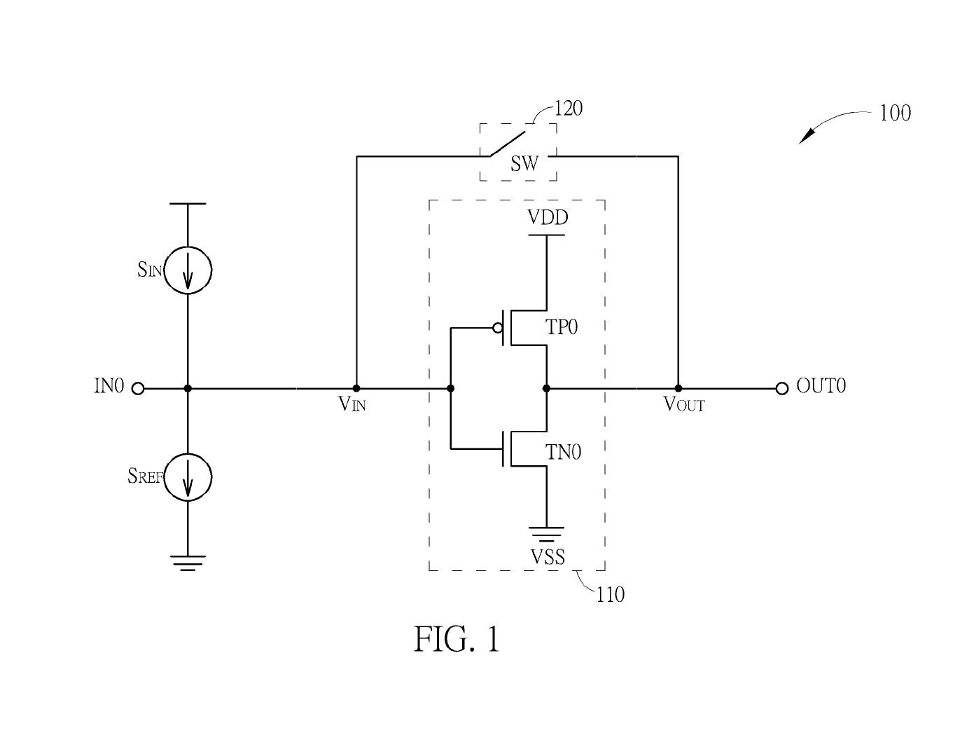

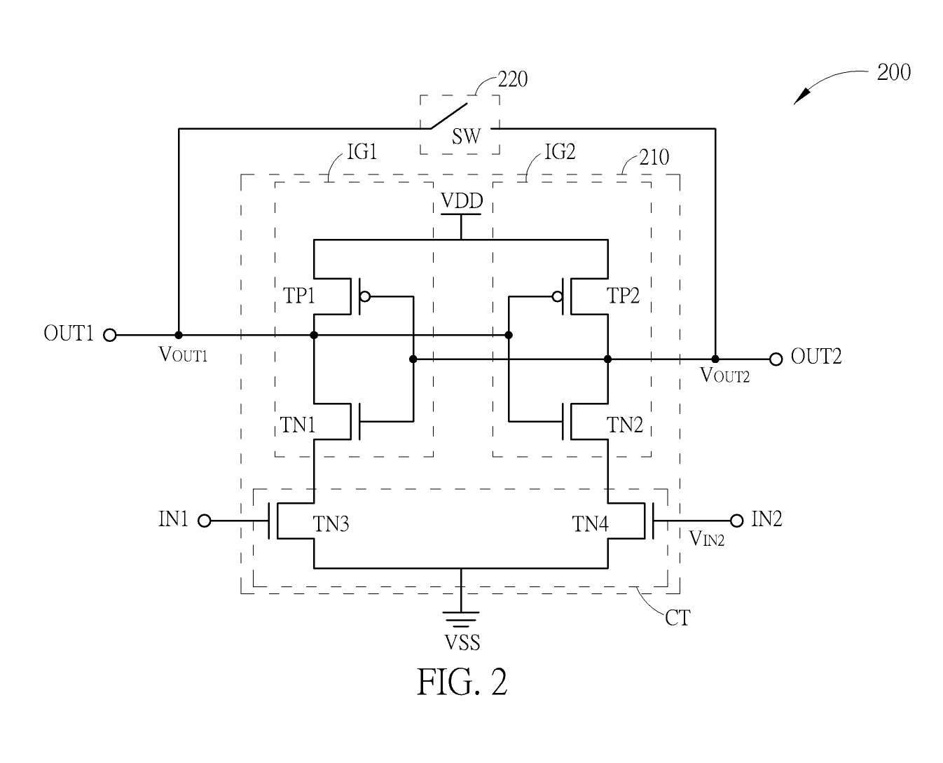

FIG. 1 is a diagram illustrating a sense amplifier 100 according to an embodiment of the present invention. The sense amplifier 100 adopts a single-ended current-latch scheme and includes an input node IN0, an output node OUT0, a sensing circuit 110 and an equalizing circuit 120. The input node IN0 is arranged to receive an input signal S_{IN} and a reference signal S_{REF}. The output node OUT0 is arranged to output an output signal V_{OUT} which reflects the input signal S_{IN}. The sensing circuit 110, coupled between the input node IN0 and the output node OUT0, is configured generate the output signal V_{OUT} according to the potential V_{IN} of the input node IN0. More precisely, the sensing circuit 110 is configured to generate the output signal V_{OUT} whose potential represents the opposite logic level to the input signal S_{IN}. In the present invention, the input signal S_{IN} may be provided by a memory cell of a memory device, such as a non-volatile memory. The reference signal S_{REF} may be provided by a dummy memory cell of the memory device or a band-gap circuit. In FIG. 1, the input signal S_{IN} and the reference signal S_{REF} are depicted as current sources for illustrative purposes and do not limit the scope of the present application.

In the sense amplifier 100 of the present invention, the sensing circuit 110 may include an inverting logic gate which is constructed with metal-oxide-semiconductor (MOS) transistors, bipolar junction transistors (BJT) or other devices with similar functions in a resistor-transistor logic (RTL), a transistor-transistor logic (TTL) or other configurations. In the embodiment illustrated in FIG. 1, the sensing circuit 110 includes a cross-coupled inverting logic gate having a p-channel transistor TP0 and an n-channel transistor TN0. The source terminals of the transistors TP0 and TN0 are coupled to bias voltages VDD and VSS, respectively. The gate terminals of the transistors TP0 and TN0 are coupled to the input node IN0. The drain terminals of the transistors TP0 and TN0 are coupled to the output node OUT0. The embodiment of the sensing circuit 110 depicted in FIG. 1 is only for illustrative purposes and does not limit the scope of the present application.

The equalizing circuit 120, coupled between the input node IN0 and the output node OUT0, is configured to bring the sensing circuit 110 to a metastable state from which the sensing circuit 110 may promptly switches to a high-level state or a low-level state in response to the input signal S_{IN}. In the embodiment illustrated in FIG. 1, the equalizing circuit 120 includes a switch SW which is turned on (shorted-circuited) before the read operation for equalizing the potentials of the input node IN0 and the output node OUT0. After turning off (open-circuited) the switch SW, the potentials of the input node IN0 and the output node OUT0 are both brought to V_{M}, which is greater than a maximum logic 0 level and less than a minimum logic 1 level.

The value of the input signal S_{IN} depends on whether the memory cell is in the high or low conductivity state. After the reading of the memory cell starts, the voltages present on the input node IN0 begins to change in a way that depends on the pull strength of the input current S_{IN} and the reference current S_{REF}. If the memory cell is in the high conductivity state, the input signal S_{IN} pulls more than the reference signal S_{REF}, thereby increasing the potential V_{IN} of the input node IN0. After V_{IN} becomes sufficiently large to turn on the transistor TN0, the sensing circuit 110 promptly switches from the metastable state to the low-level state and generates the low-level output signal V_{OUT} representing the memory cell in the high conductivity state. If the memory cell is in the low conductivity state, the reference signal S_{REF} pulls more than the input signal S_{IN}, thereby decreasing the potential V_{IN} of the input node IN0. After V_{IN} becomes sufficiently small to turn on the transistor TP0, the sensing circuit 110 promptly switches from the metastable state to the high-level state generates the high-level output signal V_{OUT} representing the memory cell in the low conductivity state.

As previously stated, the characteristics of the devices in the sensing circuit 110 may vary due to die-to-die PVT variations. In other words, the transistors TP0 and TN0 may have different performances when switching between logic 0 and logic 1. The equalizing circuit 120 in the present invention may bring the sensing circuit 110 to the metastable state in which the input node IN0 and the output node OUT0 are both set to V_{M}. The value of V_{M} is between logic 0 and logic 1, and is associated with the overall characteristic of the sensing circuit 110. Therefore, each transistor may switch to logic 0 or logic 1 faster and die-to-die PVT variations may be compensated, thereby providing high speed and low offset read operation.

FIG. 2 is a diagram illustrating a sense amplifier 200 according to another embodiment of the present invention. The sense amplifier 200 adopts a differential current-latch scheme and includes two input nodes IN1˜IN2, two output nodes OUT1˜OUT2, a sensing circuit 210 and an equalizing circuit 220. The input node IN1 is arranged to receive an input signal V_{IN1} and the input node IN2 is arranged to receive an input signal V_{IN2}. The output node OUT1 is arranged to output an output signal V_{OUT1}, and the output node OUT2 is arranged to output an output signal V_{OUT2.} The sensing circuit 210, coupled to the input nodes IN1˜IN2 and the output nodes OUT1˜OUT2, is configured generate the output signals V_{OUT1}˜V_{OUT2} according to the potentials of the input nodes IN1˜IN2. More precisely, the potential difference between the output signals V_{OUT1} and V_{OUT2} may reflect the potential difference between the input signals V_{IN1} and V_{IN2}. In the present invention, the input signal V_{IN1} and V_{IN2} may be provided by a memory cell of a memory device, such as a non-volatile memory. In one embodiment, the input signal V_{IN1} may be provided by a bit line of the memory cell and the input signal V_{IN2} may be provided by a bit line bar (inverted signal with respect to that of the bit line) of the memory cell.

In the present invention, the sensing circuit 210 may include inverting logic gates which are constructed with MOS transistors, BJTs or other devices with similar functions in a four-transistor (4T), six-transistor (6T) or other configurations. In the embodiment illustrated in FIG. 2, the sensing circuit 210 includes two cross-coupled inverting logic gates IG1˜IG2 and a control section CT. The input of the inverting logic gates IG1 is connected to the output of the inverting logic gates IG2 and vice-versa. The inverting logic gates IG1 includes for example a p-channel transistor TP1 and an n-channel transistor TN1 having their drain terminals connected to the output node OUT1 and their gate terminals connected to the output node OUT2. The inverting logic gates IG2 includes for example a p-channel transistor TP2 and an n-channel transistor TN2 having their drain terminals connected to the output node OUT2 and their gate terminals connected to the output node OUT1. The source terminals of the transistor TP1 and TP2 are connected to a bias voltage VDD. The source terminals of the transistor TN1 and TN2 are connected to a bias voltage VSS via the control section CT. The control section CT includes for example two n-channel transistor TN3˜TN4 having their drain terminals respectively connected to the source terminals of the transistors TN1˜TN2, their gate terminals respectively connected to the input node IN2˜IN2, and their drain terminals connected to the bias voltage VSS. The embodiment of the sensing circuit 210 depicted in FIG. 2 is only for illustrative purposes and does not limit the scope of the present application.

The equalizing circuit 220, coupled between the output nodes OUT1 and OUT2, is configured to bring the sensing circuit 210 to the metastable state from which the sensing circuit 210 may promptly switches to an inverting state in response to in response to the potential difference between the input node IN1 and the input node IN2 crossing a predetermined value. In the embodiment illustrated in FIG. 2, the equalizing circuit 220 includes a switch SW which is turned on (shorted-circuited) before the read operation for equalizing the potentials of the output nodes OUT1 and OUT2. After turning off (open-circuited) the switch SW, the potentials of the output nodes OUT1 and OUT2 are both brought to V_{M}, which is greater than a maximum logic 0 level and less than a minimum logic 1 level.

Before the read operation, the input nodes IN1˜IN2 are set to a precharge level by a precharge circuit (not shown) and the output nodes OUT1˜OUT2 are set to V_{M} by the equalizing circuit 220. After the reading of the memory cell starts, the voltages present on the input nodes IN1˜IN2 begin to decrease at different rates, creating a potential difference that depends on whether the memory cell is in the high or low conductivity state. The voltage difference between the input nodes IN1˜IN2 is amplified by the sensing circuit 210 and an amplified voltage difference appears between the output nodes OUT1˜OUT2. If the memory cell is in the high conductivity state, the voltage present on the input node IN1 drops more quickly than that on the input node IN2. If the memory cell is in the low conductivity state, the voltage present on the input node IN1 drops more slowly than that on the input node IN2. When the potential difference between the input nodes IN1 and IN2 becomes sufficiently large, the sensing circuit 210 promptly switches from the metastable state to the inverting state in which the voltage difference established between the output nodes OUT1˜OUT2 reflects the voltage difference between the input nodes IN1˜IN2.

As previously stated, the characteristics of the devices in the sensing circuit 210 may vary due to die-to-die PVT variations. In other words, the transistors TP1˜TP2 and TN1˜TN4 may have different performances when switching between logic 0 and logic 1. The equalizing circuit 220 in the present invention may bring the sensing circuit 210 to the metastable state in which the gates of the transistors TP1˜TP2 and TN1˜TN2 are set to V_{M}. The value of V_{M} is between logic 0 and logic 1, and is associated with the overall characteristic of the sensing circuit 210. Therefore, each transistor may switch to logic 0 or logic 1 faster and die-to-die PVT variations may be compensated, thereby providing high speed and low offset read operation.

Those skilled in the art will readily observe that numerous modifications and alterations of the device and method may be made while retaining the teachings of the invention. Accordingly, the above disclosure should be construed as limited only by the metes and bounds of the appended claims.

1-7. (canceled)

8. A differential sense amplifier, comprising:
a first input node arranged to receive a first input signal;
a second input node arranged to receive a second input signal;
a first output node arranged to output a first output signal;
a second output node arranged to output a second output signal;
a sensing circuit coupled to the first input node, the second input node, the first output node and the second output node, and configured to:
detect a potential of the first input node and a potential of the second input node; and
generate the first output signal and the second output signal according to a potential difference between the first input node and the second input node in an inverting state, wherein a potential difference between the first output signal and the second output signal reflects the potential difference between the first input signal and the second input signal; and
an equalizing circuit connected between the first output node and the second output node and configured to couple the first output node and the second output node to a voltage associated with a characteristic of the sensing circuit so as to bring the sensing circuit to a metastable state from which the sensing circuit switches to the inverting state in response to the potential difference between the first input node and the second input node crossing a predetermined value.

9. The sense amplifier of claim 8, wherein the sensing circuit includes:
a first section configured to supply the first output signal according to the first input signal and the second input signal; and
a second section configured to supply the second output signal according to the first input signal and the second input signal.

10. The sense amplifier of claim 9, wherein the first section of the sensing circuit includes at least a first inverting logic gate, the second section of the sensing circuit includes at least a second inverting logic gate, and the first and second inverting logic gates are cross-coupled.

11. The sense amplifier of claim 9, wherein:
the first section of the sensing circuit includes:
a first transistor including:
a first end;
a second end coupled to the first output node; and
a control end coupled to the second output node; and
a second transistor including:
a first end coupled to the first output node;
a second end; and
a control end coupled to the second output node; and
the second section of the sensing circuit includes:
a third transistor including:
a first end coupled to the first end of the first transistor;
a second end coupled to the second output node; and
a control end coupled to the first output node; and
a fourth transistor including:
a first end coupled to the second output node;
a second end; and
a control end coupled to the first output node.

12. The sense amplifier of claim 11, further comprising a third section having:
a fifth transistor including:
a first end coupled to the second end of the second transistor;
a second end; and
a control end arranged to receive the first input signal; and
a sixth transistor including:
a first end coupled to the second end of the fourth transistor;
a second end coupled to the second end of the fifth transistor; and
a control end arranged to receive the second input signal.

13. The sense amplifier of claim 8, wherein the potentials of the first output node and the second output node are set to a value between a maximum logic 0 level and a minimum logic 1 level in the metastable state.

14-20. (canceled)
